(19) United States
(12) Patent Application Publication
(10) Pub. No.: US 2025/0351329 A1
(43) Pub. Date: Nov. 13, 2025

(54) NON-LINE-OF-SIGHT JUNCTION FORMATION

(71) Applicant: Applied Materials, Inc., Santa Clara, CA (US)

(72) Inventors: Zhijun Chen, San Jose, CA (US); Hoi-Sung Chung, Sunnyvale, CA (US); Fredrick David Fishburn, Belmont, CA (US); Chang Seok Kang, Santa Clara, CA (US); Tomohiko Kitajima, San Jose, CA (US); Raghuveer S. Makala, Campbell, CA (US); Balasubramanian Pranatharthiharan, San Jose, CA (US); Lequn Liu, San Jose, CA (US)

(73) Assignee: Applied Materials, Inc., Santa Clara, CA (US)

(21) Appl. No.: 18/657,458

(22) Filed: May 7, 2024

(51) Int. Cl. H10B 12/00

(52) U.S. Cl. CPC H10B 12/05

(57) ABSTRACT

Semiconductor processing methods and semiconductor structures are provided with improved doping in target regions at low thermal budgets. Methods include providing a semiconductor structure with one or more undoped non-line-of-sight target regions on a substrate within a semiconductor processing chamber, where one or more low thermal budget features are formed on the semiconductor structure. Methods include subjecting the one or more undoped target regions to a pre-clean operation, removing at least a portion of any oxide present on the one or more undoped target regions. Methods include epitaxially depositing a first junction layer having a first doping concentration of less than 1×10²⁰ dopant atoms per cm⁻³ over the substrate. Methods include epitaxially depositing a second junction layer having a second doping concentration of greater than 1×10¹⁹ dopant atoms per cm⁻³ over the first junction layer.

### TECHNICAL FIELD

The present technology relates to deposition and removal processes and chambers. More specifically, the present technology relates to systems and methods for forming junctions in non-line-of-sight locations, including high aspect ratio structures.

### BACKGROUND

Integrated circuits are made possible by processes which produce intricately patterned material layers on substrate surfaces. Producing patterned material on a substrate requires controlled methods for forming and removing material. Material characteristics may affect how the device operates and may also affect how the films are removed relative to one another. Deposition processes produce films having certain characteristics. Many films that are formed require additional processing to adjust or enhance the material characteristics of the film in order to provide suitable properties.

Thus, there is a need for improved systems and methods that can be used to produce high quality devices and structures. These and other needs are addressed by the present technology.

### BRIEF SUMMARY

The present technology is generally directed to semiconductor processing methods and systems. Methods include providing a semiconductor structure with one or more undoped non-line-of-sight target regions on a substrate within a semiconductor processing chamber, where one or more low thermal budget features are formed on the semiconductor structure. Methods include subjecting the one or more undoped target regions to a pre-clean operation, removing at least a portion of any oxide present on the one or more undoped target regions. Methods include epitaxially depositing a first junction layer having a first dopant concentration of less than 1×10²⁰ dopant atoms per cm⁻³ over the substrate. Methods include epitaxially depositing a second junction layer having a second dopant concentration of greater than 1×10¹⁹ dopant atoms per cm⁻³ over the first junction layer. Methods include where a temperature within the semiconductor processing chamber is maintained at less than or about 800° C.

In embodiments, a temperature within the semiconductor processing chamber is maintained at less than or about 750° C. Moreover, in embodiments, methods further include subjecting the one or more target regions to a hydrogen bake prior to epitaxially depositing the first junction layer, where the hydrogen bake is conducted at a temperature of less than or about 750° C. In further embodiments, the one or more target regions is disposed in a recess located within the semiconductor structure. Additionally or alternatively, in embodiments, the one or more target regions is disposed within a feature having a width of 10 nm or less. Embodiments include where the semiconductor structure is maintained in an oxygen free atmosphere during the pre-clean operation, during epitaxially depositing the first junction layer, during epitaxially depositing the second junction layer, or a combination thereof. In yet more embodiments, the pre-clean operation is integrated into the semiconductor processing chamber. In embodiments, methods also include annealing the semiconductor structure after epitaxially depositing the second junction layer, where the annealing is conducted at a temperature of less than or about 1100° C. In embodiments, the annealing is conducted for a period of time and/or a temperature, forming a linear dopant gradient or a logarithmic dopant gradient, extending from an exterior surface of the second junction layer to the substrate. Embodiments include where the one or more low thermal budget features include a bitline contact.

The present technology is also generally directed to semiconductor processing systems. Systems include a first processing chamber, a second processing chamber, a third processing chamber; and a system controller. Systems include where the controller is configured to remove at least a portion of any oxide present on one or more undoped target regions of a semiconductor structure in a first processing chamber. Systems include where the one or more undoped target regions includes one or more non-line-of-sight target regions on a substrate of a semiconductor structure positioned within a semiconductor processing chamber, where one or more low thermal budget features are formed on the semiconductor structure. Systems include where the controller is configured to epitaxially deposit a first junction layer having a first doping concentration of less than 1×10²⁰ dopant atoms per cm⁻³ over the substrate in a second processing chamber, and epitaxially deposit a second junction layer having a second doping concentration of greater than 1×10¹⁹ dopant atoms per cm⁻³ over the first junction layer in a third processing chamber.

In embodiments, the semiconductor processing system includes a cluster tool. Furthermore, in embodiments, the semiconductor processing system maintains an oxygen free atmosphere during the oxide removal, during epitaxially depositing the first junction layer, during epitaxially depositing the second junction layer, between oxide removal and epitaxially depositing the first junction layer, between epitaxially depositing the first junction layer and epitaxially depositing the second junction layer, or a combination thereof. In more embodiments, the semiconductor processing system maintains a temperature at less than or about 750° C. In embodiments, the controller is further configured to subject the one or more target regions to a hydrogen bake prior to epitaxially depositing the first junction layer, wherein the hydrogen bake is conducted at a temperature of less than or about 750° C. In yet more embodiments, the controller is further configured to anneal the semiconductor structure after epitaxially depositing the second junction layer, where the annealing is conducted at a temperature of less than or about 1100° C.

The present technology is also generally directed to semiconductor processing systems. Systems include a system controller configured to remove at least a portion of any oxide present on one or more undoped target regions of a semiconductor structure, the one or more undoped target regions including one or more non-line-of-sight target regions on a substrate of a semiconductor structure positioned within a semiconductor processing chamber, where one or more low thermal budget features are formed on the semiconductor structure. Systems include a system controller configured to epitaxially deposit a first junction layer having a first doping concentration of less than 1×10²⁰ dopant atoms per cm⁻³ over the substrate and epitaxially deposit a second junction layer having a second doping concentration of greater than 1×10¹⁹ dopant atoms per cm⁻³ over the first junction layer. Systems include where a temperature within the semiconductor processing chamber is maintained at less than or about 800° C.

In embodiments, the semiconductor structure includes a 3D DRAM device. Furthermore, in embodiments, the semiconductor structure includes a 4F² device, where the one or more undoped target regions is disposed in or adjacent to a feature having a width of less than or about 10 nm. In more embodiments, the one or more undoped target regions has a length from an exposed surface to an interior end of greater than or about 40 nm.

Such technology may provide numerous benefits over conventional processing methods. For example, doping as discussed herein may provide for the doping of non-line-of-sight locations, including high aspect ratio junctions and recessed structures. Additionally, the doping processes and methods discussed herein may provide carefully tailored dopant levels, including higher doping levels than those achievable utilizing solid state doping with high aspect ratio structures or recessed structures. Processes and methods discussed herein may also achieve such doping levels without requiring additional thermal budget, reducing process steps and preventing damage to high aspect ratio features. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to embodiments of the present technology.

FIG. 2 shows a schematic cross-sectional view of an exemplary plasma system according to embodiments of the present technology.

FIG. 3 shows operations of an exemplary method of semiconductor processing according to embodiments of the present technology.

FIGS. 4A and 4B show cross-sectional views of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As the DRAM industry moves from planar 6F² schemes to 4F² vertical channel transistors schemes or 3D DRAM, the need for processes that adapt to complex transistor schemes continues to significantly increase. The evolving transistor schemes have developed devices with one or more recesses from a main channel, causing non-line-of-sight features to evolve, as well as increasingly high aspect ratio features. For instance, during 3D DRAM processing, silicon channels are formed when other materials, including silicon nitride and silicon oxide, form high aspect ratio features around a silicon material substrate material. In subsequent processing, source and drain junction regions are formed by doping the substrate material at a distal end of the high aspect ratio feature. Subsequent processing may form contacts on the source and drain regions, such as by silicidation processes.

Conventional doping of silicon-containing materials in high aspect ratio structures may be done by plasma implant processes or a solid-phase doping processes, such as conformal deposition of a dopant containing film and a drive in anneal operation followed by removal of the dopant containing film. Depending on the specific design of the device, the silicon may be doped to be p-type or n-type silicon. A portion of the dopant in the doped silicon or implant may travel into the underlying silicon-containing materials, thereby doping the underlying silicon-containing materials. However, as device complexity and aspect ratios increase, in conjunction with growing demand for high quality structures, these conventional technologies may not provide adequate doping depths, concentrations, and/or gradients, particularly at low temperatures, as conventional technologies rely upon the anneal process to convey the dopant concentration to the underlying material.

Additionally, conventional technologies deposit byproduct materials elsewhere on the structures that may frustrate subsequent processing, requiring intermediate processing to remove the byproduct material, or reduce final device function. Specifically, when solid phase doping is used, it can be difficult to remove some or all of the dopant containing film after the drive-in anneal, particularly without damaging the underlying channels. Namely, removing the deposited material without removing the now doped silicon has proven challenging. Thus, current processes are problematic, particularly for thin channels, such as channels having a width of less than 10 nm, and other high aspect ratio channels, as they frequently result in damage to the channel, resulting in decreases in electrical properties.

In addition, existing plasma processes require line-of-sight from the plasma source to the targeted doping region. This is problematic for structures that have corners or angled walls separating channels from central apertures (e.g. recessed devices). For instance, 3D DRAM structures have vertically extending holes and a plurality of channels recessing horizontally from the vertically extending hole. Thus, existing plasma technology is not capable of doping regions within the horizontal channels, due to the lack of linear pathway to the plasma source. Attempts have been made to utilize gas phase doping to overcome problems associated with solid phase doping and/or plasma processes. However, gas phase doping requires high enough temperatures to drive the dopant into the substrate material of the channel. This can be problematic, as many structures may have a limited thermal budget at the time the gas phase doping occurs or is desired to occur. For instance, in 3D DRAM structures, a bit line contact may have already been formed prior to formation of the junction. As known in the art, such contacts may include one or more silicides, which limit the subsequent thermal budget. Additionally or alternatively, as known in the art, subsequent high temperature steps may also alter the formed junction profile, creating differences in the planned junction.

The present technology has surprisingly found that by utilizing a carefully controlled integration, a low temperature dopant process can be provided at non-line-of-sight locations. Furthermore, the present technology has found that controlled dopant gradients can be provided, even at low temperatures, allowing junctions to be formed in devices with low thermal budgets. In addition, the present technology has surprisingly found that by carefully controlling junction doping as discussed herein, a full doping gradient or spectrum can be provided to the target non-line-of-sight location. Namely, the processes and systems discussed herein also address previous problems associated with undesired residual doping, such as from attempting to provide a low dopant concentration material over a high dopant concentration material.

Although the remaining disclosure will routinely identify specific deposition and etch processes utilizing the disclosed technology, it will be readily understood that the systems and methods are equally applicable to other deposition and etch chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

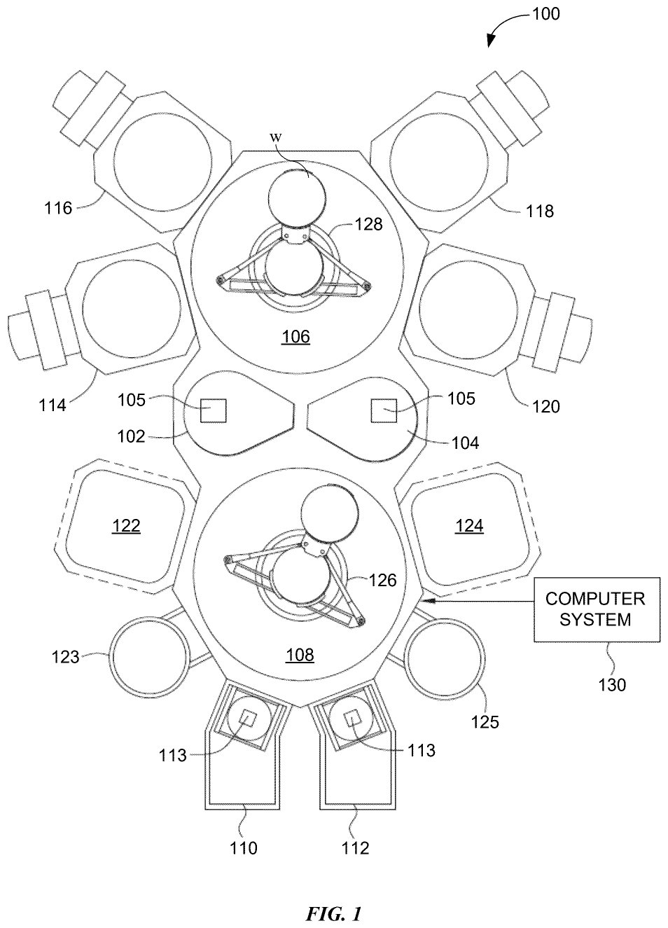

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

To transport substrates among the chambers, the transfer chamber 106 and/or buffer chamber 108 may contain a robotic transport mechanism 126, 128. The transport mechanism 126, 128 may have a pair of substrate transport blades attached to the distal ends of extendible arms, as well as other transport arms as known in the art. The blades and/or arms may be used for carrying individual substrates to and from the process chambers. In operation, one of the substrate transports may retrieve a substrate W from one of the load lock chambers such as load locks 110, 112 and carry substrate W to a first stage of processing, for example, a treatment process as described below in one or more of processing chambers 114, 116, 118, 120, 122, and 124. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber and may insert a new substrate with subsequently or with one or more second arms. Once the substrate is processed, it may then be moved to a second stage of processing. For each move, the transport mechanism 126, 128 generally may have one blade carrying a substrate and one blade empty to execute a substrate exchange. The transport mechanism 126, 128 may wait at each chamber until an exchange can be accomplished. Once processing is complete within the process chambers, the transport mechanism 126, 128 may move the substrate W from the last process chamber into a second process chamber, and/or may transport the substrate W to a cassette within the load lock chambers 110, 112.

Each of processing chambers 114, 116, 118, 120, 122, and 124 may be configured to perform one or more process steps in the fabrication of a semiconductor structure, and any number of processing chambers and combinations of processing chambers may be used on multi-chamber processing system 100. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 100, including any process described below, as would be readily appreciated by the skilled artisan.

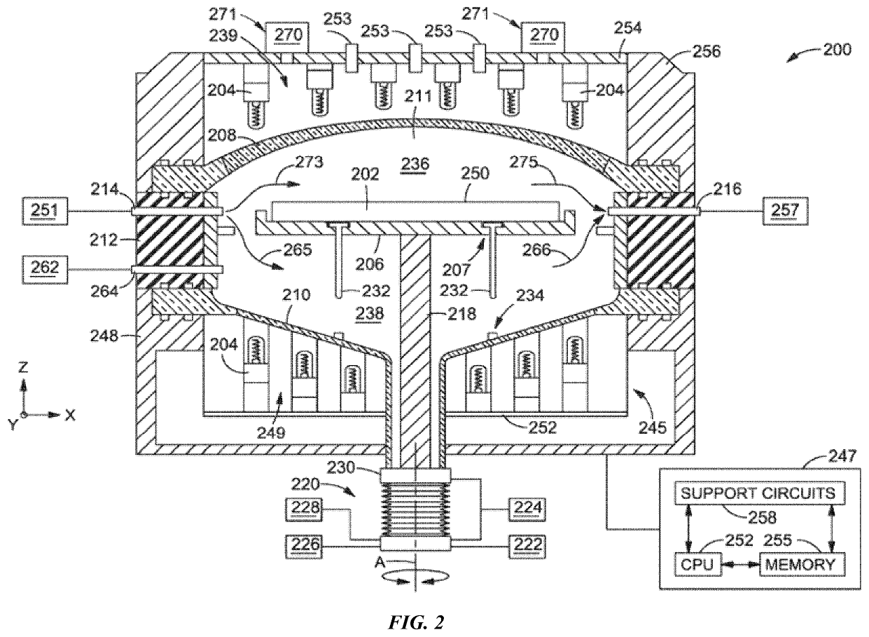

FIG. 2 illustrates a schematic cross-sectional view of an exemplary processing chamber 200 suitable for patterning a material layer disposed on a substrate 302, depositing one or more material layers, and/or providing one or more doping layers as discussed herein, in the processing chamber 100. The process chamber 200 may be used to process one or more substrates therein, including the processes of depositing a material on a device side 250 of a substrate 202, heating of the substrate 202, etching of the substrate 202, or combinations thereof. The process chamber 200 may include a chamber wall 248, and an array of radiant heating lamps 204 for heating, among other components, a substrate support 206 and/or a substrate 202 thereon, disposed within the process chamber 200. As shown in FIG. 2, an array of radiant heating lamps 204 may be disposed below (i.e. facing the non-device side of) the substrate support 206. As shown in FIG. 2, an array of radiant heating lamps 204 may be disposed below and/or above the substrate support 206. The substrate support 206 may be a disk-like substrate support as illustrated, or may include a ring-like substrate support (not shown), which supports the substrate 202 from the edge of the substrate to expose a backside of the substrate 202 directly to heat from the radiant heating lamps 204. In embodiments, the substrate support 206 may be fabricated from silicon carbide or graphite coated with silicon carbide to absorb radiant energy from the lamps 204 and conduct the radiant energy to the substrate 202, thus heating the substrate 202.

The substrate support 206 may be located within the process chamber 200 between a first energy transmissive member 208, which may be a dome, and a second energy transmissive member 210, which may also or independently be a dome. The first energy transmissive member 208 and the second energy transmissive member 210, along with a body 212 which may be disposed between the first energy transmissive member 208 and second energy transmissive member 210, may generally define an internal region 211 of the process chamber 200. The first energy transmissive member 208 and/or the second energy transmissive member 210 may be convex and/or concave. In embodiments, The first energy transmissive member 208 and/or the second energy transmissive member 210 may be optically transparent to the high-energy radiant radiation (transmitting at least 95% of the radiation of the high-energy radiant radiation). In one embodiment, the first energy transmissive member 208 and the second energy transmissive member 210 are fabricated from quartz. In embodiments, the array of radiant heating lamps 204 may be disposed above the first energy transmissive member 208, for example, a region 239 defined between the first energy transmissive member 208 and a reflector 254 (discussed in greater detail below). In embodiments, the array of the radiant heating lamps 204 may be disposed adjacent to and beneath the second energy transmissive member 210. The radiant heating lamps 204 may be independently controlled in zones in order to control the temperature of various regions of the substrate 202 as a process gas or vapor passes over the surface of the substrate 202, thus facilitating the deposition or doping of a material onto the device side 250 of the substrate 202. In embodiments, a deposited material may include elemental semiconductor materials such as silicon, doped silicon, germanium, and doped germanium; semiconductor alloys such as silicon germanium and doped silicon germanium; and compound semiconductor materials, including III-V materials, examples of which include nitrides, phosphides, and arsenides of aluminum, gallium, indium, and thallium, and mixtures thereof, and II-VI materials, examples of which include sulfides, selenides and tellurides of zinc, cadmium, and mixtures thereof.

The radiant heating lamps 204 may provide a total lamp power of between about 10 KW and about 60 KW, and are configured to heat the substrate 202, for example to a temperature within a range of about 200° C. to about 1,600° C. and/or according to any one or more of the process condition temperatures discussed in greater detail below. Each lamp 204 can be coupled to a power distribution board, such as printed circuit board (PCB) 252, through which power is supplied to each lamp 204. In one embodiment, the radiant heating lamps 204 are positioned within a housing 245 which is configured to be cooled during or after processing by, for example, using a cooling fluid introduced into channels 249 located between the radiant heating lamps 204. However in embodiments, it should be clear that other heating methods and apparatus may be used alone or in conjunction with heating lamps 204. Such as, in embodiments, a heated or cooled substrate support 206.

The substrate 202 is transferred into the process chamber 200 and positioned onto the substrate support 206 through a loading port (discussed in greater detail in regards to FIG. 1) formed in the body 212. A process gas inlet 214 and a gas outlet 216 are provided in the body 212.

In embodiments, the substrate support 206 may include a shaft or stem 218 that is coupled to a motion assembly 220. The motion assembly 220 may include one or more actuators and/or adjustment devices that provide movement and/or adjustment of the position of the stem 218 and/or the substrate support 206 within the internal region 211. For example, the motion assembly 220 may include a rotary actuator 222, as an example, that rotates stem 218, and thus the substrate support 206, about the longitudinal axis A of the process chamber 200 perpendicular to an X-Y plane of the process chamber 200. The motion assembly 220 may also include a vertical actuator 224 to move the stem 218, and thus substrate support 206, in the Z direction (e.g. vertically) within the process chamber 200. In embodiments, the motion assembly 220 optionally includes a tilt adjustment device 226 that is used to adjust the planar orientation of the substrate support 206 in the internal region 211. The motion assembly 220 optionally also may include a lateral adjustment device 228 that is utilized to adjust the positioning of the stem 218 and/or the substrate support 206 in the x-y plane of the process chamber 200 within the internal region 211. In embodiments, the motion assembly 220 may include a pivot mechanism 230.

The substrate support 206 is shown in an elevated processing position but may be lifted or lowered vertically by the motion assembly 220 as described above. For instance, the substrate support 206 may be lowered to a transfer position (below the processing position) to allow lift pins 232 to contact standoffs 234 on or above the second energy transmissive member 210. The stand-offs provide one or more surfaces parallel to the X-Y plane of the process chamber 200 and help to prevent binding of the lift pins 232 that may occur if the end thereof is allowed to contact the curved surface of the second energy transmissive member 210. The stand-offs 234 are made of an optically transparent material in embodiments, such as quartz, to allow energy from the lamps 204 to pass therethrough. The lift pins 232 may be suspended in holes 207 in the substrate support 206, and as the substrate support 206 is lowered and the bottom of the lift pins 232 engage the standoffs 234. Thus, in embodiments, further downward movement of the substrate support 206 may cause the lift pins 232 to engage the substrate 202 and hold it stationary as the substrate support 206 is further lowered, and thus support the substrate in a position spaced apart from the substrate support 206 for transfer thereof from the process chamber 200. A robot (as discussed in greater detail in FIG. 1) then enters the process chamber 200 to engage at least the underside of the substrate 202 and remove the substrate 202 therefrom though the loading port. A new substrate 202 may then be loaded onto the lift pins 232 by the robot, and the substrate support 206 may then be actuated up to the processing position to place the substrate 202 thereon, with its device side 250 facing up. The lift pins 232 may include an enlarged head allowing the lift pins 232 to be suspended in openings in the substrate support 206 when in the processing position. The substrate support 206, while located in the processing position, may divide the internal volume of the process chamber 200 into a processing region 236 above the substrate support 206, and a purge region 238 below the substrate support 206.

The substrate support 206 may be rotated during processing, such as by rotary actuator 222, to minimize the effect of thermal and process gas flow spatial anomalies within the process chamber 200 and thus facilitates uniform processing of the substrate 202. In embodiments, the substrate support 206 may rotates at a speed a between about 5 RPM and about 100 RPM, such as between about 10 RPM and about 50 RPM, for example about 15 RPM to about 45 RPM.

Substrate temperature may be measured by sensors configured to measure temperatures at one or more locations on the substrate or along the bottom of the substrate support 206. The sensors may be pyrometers (not shown) disposed in ports formed in the housing 245. Additionally or alternatively, one or more sensors 253, such as a pyrometer, may be used to measure the temperature of the device side 250 of the substrate 202. For instance, a reflector 254 may be optionally placed outside the first energy transmissive member 208 to reflect infrared light that is radiating off the substrate 202 and redirect the energy back onto the substrate 202. The reflector 254 may be secured to the first energy transmissive member 208 using a clamp ring 256. The reflector 254 can be made of a metal such as aluminum or stainless steel, or other materials as known in the art. The sensors 253 can be disposed through the reflector 254 to receive radiation from the device side 250 of the substrate 202.

Process gas supplied from a process gas supply source 251 may be introduced into the processing region 236 through the process gas inlet 214 formed in the sidewall of the body 212. The process gas inlet 214 may direct the process gas in a generally radially inward direction (e.g. towards axis A of process chamber 200). As such, in embodiments, the process gas inlet 214 may be a side gas injector. The side gas injector may be positioned to direct the process gas across a surface of the substrate support 206 and/or the substrate 202. During a film formation process for forming a film layer of the substrate 202, the substrate support 206 may be located in the processing position, disposing substrate 202 in the processing region 236, thus allowing the process gas to flow generally along flow path 273 across the upper surface of the substrate support 206 and/or substrate 202. The process gas may exit the processing region 236 (such as along flow path 275) through the gas outlet 216 located on the opposite side of the process chamber 200 from the process gas inlet 214. Removal of the process gas through the gas outlet 216 may be facilitated by a vacuum pump 257 fluidly coupled to the internal region 211 as well as a system foreline (not shown).

Purge gas supplied from a purge gas source 262 may be introduced to the purge region 238 through a purge gas inlet 264 formed in the sidewall of the body 212. The purge gas inlet 264 may be disposed at an elevation below the process gas inlet 214. The purge gas inlet 264 may be configured to direct the purge gas in a generally radially inward direction. The purge gas inlet 264 may be configured to direct the purge gas in an upward direction. During a film formation process, the substrate support 206 may be located at a position such that the purge gas flows generally along flow path 265 across a back side of the substrate support 206. The purge gas may exit the purge region 238 (such as along flow path 266) and may be exhausted out of the process chamber through the gas outlet 216 located on the opposite side of the process chamber 200 as the purge gas inlet 264.

The process chamber 200 may further include a spot heating module 271. The spot heating module 271 may include one or more spot heaters 270 which may provide individual heating to one or more locations on substrate 202 during processing. For instance, in embodiments, cold spots may be formed on the substrate 202 at locations that the substrate 202 is in contact with the lift pins 232.

The above-described process chamber 200 can be controlled by a processor based system controller, such as controller 247, shown in FIGS. 2. For example, the controller 247 may be configured to control flow of various precursor and process gases and purge gases from gas sources, during different operations of a substrate processing sequence. By way of further example, the controller 247 may be configured to control a firing of the spot heating module 271, predict an algorithm for firing the spot heating module 271, and/or encode or synchronize the operation of the spot heating module 271 with substrate rotation, feeding of gases, lamp operation, or other process parameters, among other controller operations. The controller 247 includes a programmable central processing unit (CPU) 252 that is operable with a memory 255 and a mass storage device, an input control unit, and a display unit (not shown), such as clocks, cache, input/output (I/O) circuits, and the like, coupled to the various components of the process chamber 200 to facilitate control of substrate processing in the process chamber 200. The controller 247 may further include support circuits 258. To facilitate control of the process chamber 200 described above, the CPU 252 may be one of any form of general-purpose computer processor that can be used in an industrial setting, such as a programmable logic controller (PLC), for controlling various chambers and sub-processors. The memory 255 may be in the form of computer-readable storage media that contains instructions, that when executed by the CPU 252, facilitates the operation of the process chamber 200. The instructions in the memory 255 may be in the form of a program product such as a program that implements the method of the present disclosure.

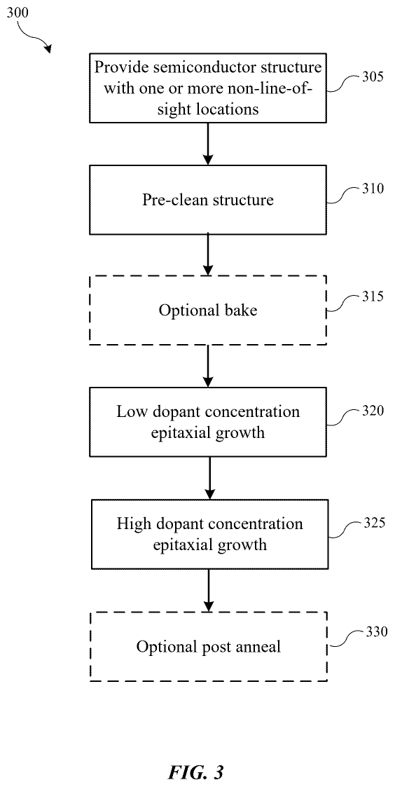

As noted above, the present technology may form a doped target region (which may be a silicon-containing material, in embodiments) utilizing one or more selective epitaxial growth processes. Turning to FIG. 3 is shown exemplary operations in a method 300 for forming a semiconductor structure according to embodiments of the present technology. Method 300 may include one or more operations prior to the initiation of the method, including front-end processing, deposition, etching, polishing, cleaning, or any other operations that may be performed prior to the described operations. For example, the method may begin after a number of layers have been deposited, such as for producing 3D DRAM structures. However, as explained above, it is to be understood that the figures illustrate just one exemplary process in which processes according to embodiments of the present technology may be employed, and the description is not intended to limit the technology to this process or structure alone. Some or all of the operations may be performed in chambers or system tools as previously described, or may be performed in different chambers on the same system tool, which may include the chamber in which the operations of method 300 may be performed.

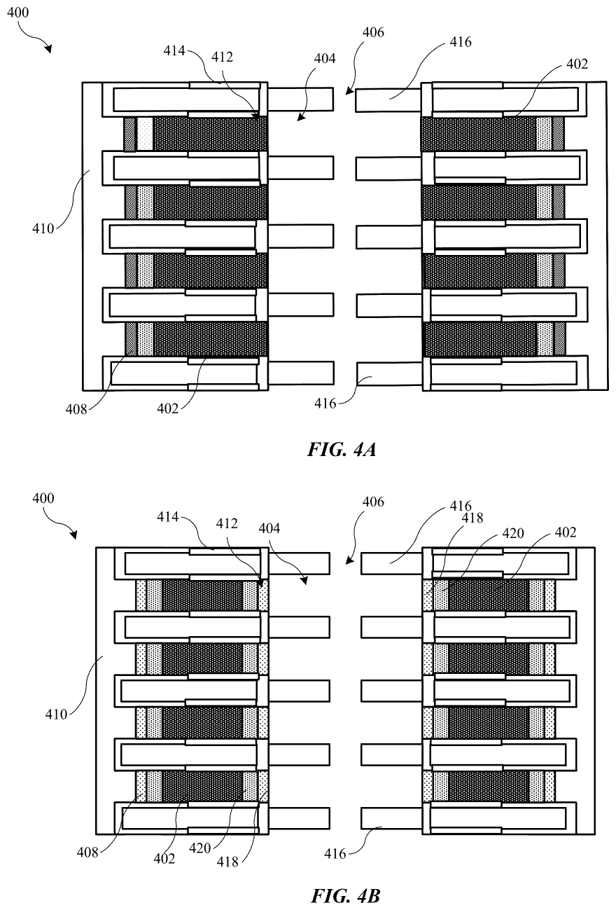

Method 300 may include a number of optional operations as illustrated, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 describes operations shown schematically in FIGS. 4A-4B, the illustrations of which will be described in conjunction with the operations of method 300. It is to be understood that FIGS. 4A-4B illustrate only partial schematic views, and a substrate may contain any number of structural sections having aspects as illustrated in the figures, as well as alternative structural aspects that may still benefit from operations of the present technology.

Method 300 may or may not involve optional operations to develop the semiconductor structure to a particular fabrication operation. It is to be understood that method 300 may be performed on any number of semiconductor structures 400, as illustrated in FIG. 4A, including exemplary structures on which it is desired to form one or more doped regions. The doped regions are illustrated herein as being doped junctions. However, it should be understood that methods and systems discussed herein are also suitable for doping other desired regions, such as any one or more non-line-of-sight locations discussed herein. Nonetheless, as illustrated in FIG. 4A a semiconductor structure 400 may have a number of layers of material deposited overlying the substrate. Semiconductor structure 400 may be formed from any number of materials, such as a base wafer or substrate made of silicon or silicon-containing materials, germanium, other substrate materials, as well as one or more materials that may be formed overlying the substrate during semiconductor processing.

Semiconductor structure 400 may illustrate a partial view of a stack of alternating layers of materials, which in some embodiments may be used in 3D DRAM memory formation or a vertically extending orientation, such as for 4F² memory formation. As shown in FIG. 4A, semiconductor structure 400 may include one or more channels 402 extending between adjacent word lines 414. In embodiments, the one or more channels may be formed from one or more materials including substrate materials, or layers thereof, such as silicon, polysilicon, amorphous silicon, doped silicon, strained silicon, carbon doped silicon dioxides, SiGe, germanium, gallium arsenide, GaN, InP, carbon nanotube, and any other materials such as lll-IV group, 2D TMD metals, metal oxides, metal nitrides, metal alloys, and other conductive materials, combinations thereof, as well as other channel materials as known in the art. As the illustrated embodiment of FIG. 4A is a 3D DRAM structure, the one or more channels 402 may extend in a generally horizontal direction, and be generally perpendicular to an access hole or aperture 406 and/or bit line 410, or a planned access hole or aperture 406 and/or planned bit line 410 location. For instance, in embodiments, the one or more channels 402 may be within about 100 from perpendicular with memory hole 406 and/or substrate 405, such as less than or about 7.5°, such as less than or about 5°, such as less than or about 2.5°, such as less than or about 1° from perpendicular, or any ranges or values therebetween. However, as discussed above, in embodiments, the bit line 410 may be formed after depositing one or more junction layers as discussed herein. In embodiments, the one or more channels 402 and the memory hole 406 may be perpendicular to one another.

However, while non-line-of sight structures, such as junctions and high aspect ratio features, have been so far discussed, it should be clear that the methods and systems discussed herein can also be used to form any semiconductor structure which has an access hole (e.g. contact hole). Thus, the present technology may be utilized to replace conventional epitaxial doping or implant doping processes for doping target material (such as a Si-containing) exposed at the bottom of the respective hole. For example, methods and systems discussed herein may also be suitable for junction doping of one or more bitline contacts or storage node contacts in current 6F² DRAM or even junction doping for logic FinFET or Nanosheet transistors, to name a few.

In embodiments, the one or more channels 402 may have a length of greater than or about 300 nm, such as greater than or about 400 nm, greater than or about 500 nm, greater than or about 600 nm, greater than or about 700 nm, or more, or any ranges or values therebetween. The one or more channels may have a width or critical dimension of greater than or about 5 nm, such as greater than or about 25 nm, greater than or about 50 nm, greater than or about 75 nm, greater than or about 100 nm, or more, or such as less than or about 50 nm, such as less than or about 40 nm, such as less than or about 30 nm, such as less than or about 25 nm, such as less than or about 20 nm, such as less than or about 15 nm, such as less than or about 10 nm, such as less than or about 5 nm, or any ranges or values therebetween. Thus, in embodiments, the channel and/or an adjacent feature may be considered to have a high aspect ratio, such as an aspect ratio of greater than or about 50, such as greater than or about 60, such as greater than or about 70, such as greater than or about 80, such as greater than or about 90, such as greater than or about 100, such as greater than or about 110, such as greater than or about 120, such as greater than or about 130, such as greater than or about 140, such as greater than or about 150, or any ranges or values therebetween.

However, as discussed above, in embodiments, the one or more channels may not have a high aspect ratio or a large height. Instead, the target region may be located in a recess 404 as illustrated in FIG. 4A. For instance, as illustrated, such a recess 404 may block the line-of-sight to a process gas or plasma source, such as through memory hole 406. In embodiments, adjacent caps 416 may form all or a portion of the recess between adjacent channels 402, but the recess may be formed by any structure or feature as known in the art. Nonetheless, in embodiments, the one or more channels 402 may have any heights, widths, or aspect ratios discussed above, in combination with being disposed in a recess 404.

The semiconductor structure 400 may also include bit line junctions 408 adjacent to a bit line 410 and storage node junctions 412 adjacent to word lines 414, as illustrated in FIG. 4A. The bit line(s) 410 may extend in a first direction with may be a generally vertical direction, and one or more word lines may extend in a second direction, which may be orthogonal to bit line(s) 410 in embodiments. Nonetheless, as discussed above, the one or more channels 402 may extend in a direction that is generally orthogonal (e.g. within about 100 from orthogonal, such as less than or about 7.5°, such as less than or about 5°, such as less than or about 2.5°, such as less than or about 1° from orthogonal, or any ranges or values therebetween) to the first direction, the second direction, or both the first and second direction. However, it should be clear that FIGS. 4A-4B are exemplary structures, and therefore, that the entire structure may be rotated, such that bit lines 410 extend in a generally horizontal orientation.

Nonetheless, as illustrated in FIG. 4A, the bit line junctions 408 may have already undergone junction doping forming bit line junction 408, such as by the process discussed herein, by gas phase doping, or by other processes as known in the art. However, in embodiments, bit line 410 may not yet be formed, and both bit line junctions 408 and storage node junctions 412 may be formed according to method 300. Nonetheless, as illustrated, storage node junctions 412 may not yet have undergone junction doping as illustrated in FIG. 4A.

Thus, in embodiments, methods according to the present technology may include providing a semiconductor structure 400 with one or more undoped target regions, such as one or more junctions, such as a storage node junction 412, and/or one or more other undoped target regions, to a processing region of a processing chamber, such as one or more processing chambers as discussed above, at operation 305. However, as discussed above, in embodiments, the semiconductor structure 400 may have one or more other regions where doping is desired. Such as one or more regions that are blocked from a plasma source, such as disposed within a recess 404 as illustrated in FIG. 4A, or disposed within a narrow and/or high aspect ratio feature. Nonetheless, in embodiments, methods and systems according to the present technology may include forming and/or providing one or more junctions on an accessible portion of the semiconductor structure (e.g. in line of sight or not within a high aspect ratio feature), such as bit line junction 408 which may include a silicide illustrated in FIG. 4A, or forming and/or providing of one or more features that reduce the thermal budget of the semiconductor structure, such as reduces the thermal budget to a temperature of less than or about 800° C., less than or about 775° C., less than or about 750° C., less than or about 725° C., less than or about 700° C., less than or about 675° C., less than or about 650° C., less than or about 625° C., less than or about 600° C., less than or about 575° C., less than or about 550° C., less than or about 525° C., less than or about 500° C., less than or about 475° C., less than or about 450° C., less than or about 425° C., such as down to about 400° C., or less, or any ranges or values therebetween.

Nonetheless, in embodiments, the semiconductor structure may undergo one or more pre-treatment and/or pre-clean operations prior to selective epitaxy process in order to remove some or all of an oxide and/or carbon present on the surface of the targeted doping region, as oxide, including native oxide, may interfere with the selective epitaxy processes discussed herein. In embodiments, the pre-clean and/or pre-treatment operation(s) may include e a wet or dry cleaning process, and may be an integrated pre-clean within the processing chamber. Alternatively, the semiconductor structure 400 may be transferred to a pre-clean chamber. However, in such an embodiments, the transfer may occur without an air-break, such as within an oxygen free atmosphere. Thus, in embodiments, regardless of whether the pre-clean operation is integrated within the chamber, or is disposed in a separate chamber, the semiconductor structure may not be extensively exposed to air or other oxygen sources after pre-clean operation 310 has commenced, or reduced levels of oxygen or air such that a continuous or discontinuous layer of native oxide, to form or re-form. While any cleaning operations suitable for removing surface oxides and/or surface carbon may be utilized, in embodiments, a preclean, such as a Siconi™ clean or a plasma etch clean may be utilized to remove any surface oxides present.

In embodiments, an optional hydrogen bake operation may be utilized at operation 315. In embodiments, such a hydrogen bake operation may not be necessary if adequate pre-cleaning is achieved at operation 310 and if no air-break has occurred. Nonetheless, in embodiments, it may be desirable to further ensure that little to no surface oxide is present in the targeted doping region. Thus, in optional embodiments, the semiconductor structure 400 may be subjected to a hydrogen bake. The hydrogen bake may include removing contaminants and defects on the surface of the semiconductor structure by flowing a hydrogen gas in conjunction with an elevated temperature of greater than or about 600° C., greater than or about 600° C., greater than or about 700° C., greater than or about 750° C., such as greater than or about 800° C., such as greater than or about 850° C., such as greater than or about 900° C., such as greater than or about 950° C., such as greater than or about 1000° C., such as greater than or about 1050° C., or any ranges or values therebetween. However, in embodiments, the hydrogen bake operation may be conducted after forming a first junction and/or one or more features that reduce the thermal budget of the semiconductor structure. Thus, in embodiments, the hydrogen bake may be limited by the thermal budget of the semiconductor structure, and may therefore be conducted at a temperature of less than or about 800° C., such as less than or about 775° C., such as less than or about 750° C., such as less than or about 725° C., such as less than or about 700° C., or any ranges or values therebetween.

Regardless of whether the optional bake operation 315 is utilized, the target region (e.g., storage node junction or region 412 in the illustrated embodiment), may contain less than or about 5 wt. % of total oxides, including native oxides, such as less than or about 4 wt. %, such as less than or about 3 wt. %, such as less than or about 2 wt. %, such as less than or about 1 wt. %, such as less than or about 0.5 wt. %, such a less than or about 0.1 wt. %, or be generally free of oxides, based upon the total weight of the targeted region.

Nonetheless, after the pre-clean operation 310 and optional bake operation 315, a first epitaxial layer having one or more first dopant concentrations, is deposited over the substrate. Namely, in embodiments, it may be desirable to form a first doped layer over the substrate, that has a lower doping concentration, including a doping concentration (dopant atoms per cubic centimeter of deposited material) as low as or about 1×10¹⁷ cm⁻³, in order to improve function of the junction. However, the present technology has surprisingly found that a single chamber is not capable of imparting such a gradient. Instead, the present technology has found that a chamber utilized to impart high dopant concentrations, such as concentrations greater than 1×10¹⁹ cm⁻³, provide an unexpectedly high dopant concentration in the low dopant epitaxy material, even when the chamber is purged, or otherwise cleaned between operations. Thus, the present technology has found that a first epitaxial layer 420 formed over channels/substrate 402 may be formed in a first selective epitaxy deposition chamber, where the first selective epitaxy deposition chamber is utilized to deposit one or more junction layers having a maximum dopant concentration of 1×10²⁰ cm⁻³, or, in embodiments 1×10¹⁹ cm⁻³.

Thus, in embodiments, operation 320 may deposit a first junction layer 420 having a low dopant concentration, over channels 402, formed from one or more substrate materials. In embodiments, the first junction layer 420 may have a dopant concentration in the deposited layer of greater than or about 5×10¹⁶ cm⁻³, such as greater than or about 6×10¹⁶ cm⁻³, such as greater than or about 7×10¹⁶ cm⁻³, such as greater than or about 8×10¹⁶ cm⁻³, such as greater than or about 9×10¹⁶ cm⁻³, such as greater than or about 1×10¹⁷ cm⁻³, such as greater than or about 2×10¹⁷ cm⁻³, such as greater than or about 4×10¹⁷ cm⁻³, such as greater than or about 6×10¹⁷ cm⁻³, such as greater than or about 8×10¹⁷ cm⁻³, such as greater than or about 1×10¹⁸ cm⁻³, such as greater than or about 2×10¹⁸ cm⁻³, such as greater than or about 4×10¹⁸ cm⁻³, such as greater than or about 6×10¹⁸ cm⁻³, such as greater than or about 8×10¹⁸ cm⁻³, such as greater than or about 1×10¹⁹ cm⁻³, greater than or about 5×10¹⁹ cm⁻³, up to about 1×10²⁰ cm⁻³, or such as less than 1×10²⁰ cm⁻³, less than or about 5×10¹⁹ cm⁻³, less than or about 1×10¹⁹ cm⁻³, such as less than or about 5×10¹⁸ cm⁻³, or any ranges or values therebetween.

As known in the art, a typical selective epitaxy process involves a deposition reaction and an etch reaction. The deposition reaction includes depositing an epitaxial layer on a monocrystalline surfaces of a substrate, such as one or more substrate materials discussed herein, and a polycrystalline and/or amorphous layer to be formed on non-monocrystalline surfaces, for example, a patterned dielectric layer or cap layer deposited atop the substrate. The subsequent etch operation selectively removes the epitaxial layer and the polycrystalline and/or amorphous layer at different rates, providing a net selective process that can result in deposition of an epitaxial material and limited, or no, deposition of a polycrystalline material and/or amorphous material. However, at low temperatures, typical etching gases may fail to provide adequate selectivity between the epitaxial layer and the polycrystalline and/or amorphous layer.

As discussed above, in embodiments, the present technology performs the epitaxial growth process of operations 320 and/or 325 at low temperatures to preserve the thermal budget of the semiconductor structure, for example, a temperature of less than or about 800° C., less than or about 750° C., less than or about 725° C., less than or about 700° C., less than or about 675° C., less than or about 650° C., less than or about 625° C., less than or about 600° C., less than or about 575° C., less than or about 550° C., less than or about 525° C., less than or about 500° C., less than or about 475° C., less than or about 450° C., less than or about 425° C., or such as greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., greater than or about 625° C., greater than or about 650° C., greater than or about 675° C., greater than or about 700° C., greater than or about 725° C., or any ranges or values therebetween.

Thus, to overcome issues related to selectivity at low temperatures, the epitaxial growth process of operation 320 and/or 325 include flowing a higher order silane and/or higher order chlorosilane, and a dopant into the processing region of a process chamber to form the doped junction layer 420, as well as potential unwanted growth (amorphous silicon) over areas not corresponding to channels/substrate 402. However, as will be discussed in greater detail below, in embodiments, other epitaxial growth materials may be utilized with the capping process, and thus, other silanes may be utilized when forming junction layer 418 and/or 420. During the epitaxial growth process of operation 320 and/or 325, positioning the substrate in a processing region of a processing chamber may include adjusting one or more reactor conditions, such as temperature, pressure, and/or carrier gas (e.g., Ar, N₂, H₂, or He) flow rate, to conditions suitable for epitaxial film formation. The epitaxial deposition process of operation 320 and/or 325 may be performed in a processing chamber positioned on a cluster tool, for example, any of the processing chambers discussed above.

The pressure in the processing chamber may be adjusted so that the reaction region pressure is within range of about 1 to about 760 Torr, or in a range from about 1 torr to about 600 torr, or in a range from about 10 torr to about 300 torr, or in a range from about 10 torr to about 100 torr. In embodiments, a carrier gas (e.g., nitrogen) may be flowed into the processing chamber at a flow rate of approximately 1 to 40 SLM (standard liters per minute). Nitrogen remains inert during low temperature deposition processes. Therefore, nitrogen is not incorporated into the deposited layers during the low temperature epitaxial growth process. Also, a nitrogen carrier gas does not form hydrogen-terminated surfaces as does a hydrogen carrier gas. However, it will be appreciated that in embodiments, a different carrier/diluent gas may be employed, for example, an inert carrier gas such as argon or helium, a different flow rate may be used, or that such gas(es) may be omitted.

In embodiments, the epitaxial growth process discussed herein may include introducing a deposition gas including a higher order silane precursor gas and/or a chlorosilane precursor gas and a dopant precursor gas including a dopant, such as a n-type or p-type dopant, precursor gas into the processing region of a process chamber. Higher order silanes include silanes with the chemical formula SiₓH₍₂ₓ₊₂₎ where x is 2 or more, for example, where x is 2, 3, 4, 5, 6, 7, 8, or more. Examples of higher order silanes include disilane (Si₂H₆), trisilane (Si₃H₈), and tetrasilane (Si₄H₁₀), or other higher order silanes. Chlorosilanes include chlorosilanes with the chemical formula Cl_{y}SiₓH_{(2x+2-y)} wherein y is 1 or more, 2 or more, 3 or more, or 5 or more, and x is one or more, or two or more, or 3 or more. In one example, y is from 5 to 8 and x is from 2 to 3. In embodiments, the second chlorosilane precursor gas includes chlorosilane (Cl_{S}iH₃), dichlorosilane (Cl₂SiH₂), trichlorosilane (Cl₃SiH), hexachlorodisilane (Si₂Cl₆), tetrachlorosilane (SiCl₄), pentachlorodisilane (Cl₅Si₂H), octachlorotrisilane (Cl₈Si₃), or a combination thereof. However, other silanes may also be utilized herein. In one example, the deposition gas is introduced into the processing region at a flow rate in a range from about 1 sccm to about 500 sccm, or in a range from about 10 sccm to about 400 sccm, or in a range from about 50 sccm to about 300 sccm, or in a range from about 100 sccm to about 200 sccm.

In embodiments, the epitaxial growth process discussed herein may include introducing a dopant precursor, such as a n-type or p-type dopant precursor, into the processing region. In embodiments, a dopant precursor such as a n-type dopant precursor includes a phosphorous containing precursor, an antimony precursor, an arsenic-containing precursor, or a combination thereof. In embodiments, the antimony-containing precursor includes one or a combination of stibine, antimony trichloride, antimony tetrachloride, antimony pentachloride, triphenylantimony, antimony trihydide, antimonytrioxide, antimony pentoxide, antimony trifluoride, antimony tribromide, antimonytriiodide, antimony pentafluoride, triethyl antimony, and trimethyl antimony, or combinations thereof. In embodiments, the phosphorous-containing precursor includes one or a combination of phosphine and alkylphosphines. Suitable alkylphosphines include trimethylphosphine ((CH₃)₃P), dimethylphosphine ((CH₃)₂PH), triethylphosphine ((CH₃CH₂)₃P), tertbutylphosphine, and diethylphosphine ((CH₃CH₂)₂PH), and combinations thereof. In embodiments, phosphine is used. In embodiments, the arsenic containing precursor includes one or a combination of arsine (AsH3), halogenated arsenic compounds, trimethylarsenic, and silylarsines [(H₃Si)₃₋ₓAsRₓ] where x=0, 1, 2, and Rx is hydrogen or deuterium. The n-type dopant precursor gas may have a flow rate in a range from about 0.1 sccm and 10,000 sccm, or in a range from about 100 sccm to about 5,000 sccm, or in a range from about 500 to about 3,000 sccm.

In embodiments, the epitaxial layer may be a silicon germanium (SiGe) layer, and the deposition gas further includes a germanium source. Suitable germanium sources include germane (GeH₄) and higher order germanes. Higher order germanes include compounds with the empirical formula GeₓH₍₂ₓ₊₂₎, where x is two or more, for example, where x is two, three, four, or more. Examples of higher order germanes include digermane (Ge₂H₆), trigermane (Ge₃H₈) and tetragermane (Ge₄H₁₀), as well as others and combinations thereof.

It is contemplated that the deposition precursor gases and the dopant precursor gases may be introduced simultaneously, substantially simultaneously, or in any targeted order. In at least one embodiment, the deposition precursor gases and the dopant precursor gases are co-flowed into the process region simultaneously. In embodiments, at least two of the precursor gases are mixed prior to being delivered to the processing region. In embodiments, at least two of the precursor gases are delivered to the processing region separately and mixed within the processing region.

Nonetheless, in embodiments, an undoped or lightly doped crystalline silicon-containing capping layer is applied over the first junction layer. Being “undoped” includes embodiments where the undoped crystalline silicon containing capping layer and the undoped amorphous silicon-containing layer are unintentionally doped or otherwise doped with very low dopant concentration such that the undoped crystalline silicon-containing capping layer and the undoped amorphous silicon-containing layer do not contain sufficient carriers (electrons or holes) to be conductive under a typical electric field. The undoped crystalline silicon containing capping layer protects the underlying doped junction layer during the subsequent selective etching process to remove the doped and undoped amorphous layers.

The undoped crystalline silicon-containing capping layer is grown over or directly on an upper surface of the first junction layer(s) (e.g. low dopant concentration junction layer) and an undoped amorphous silicon-containing layer is formed over any unintentionally deposited material formed on feature sidewalls, or other non-substrate surfaces during the first epitaxial deposition process. The epitaxial growth process forming the capping layer may utilize one or more of the above methods and materials discussed in regards to the first junction layer, but may include little to no dopant. In embodiments, the undoped crystalline silicon-containing capping layer may be grown to a thickness such that at least a portion of the undoped crystalline silicon-containing capping layer remains over the first junction layer during etching.

For instance, in embodiments, the doped amorphous silicon-containing layer and the undoped amorphous silicon-containing layer are selectively removed relative to the undoped crystalline silicon-containing capping layer, which may be only partially removed. Namely, the etching process may be tuned to be selective to the amorphous materials of the undoped amorphous silicon-containing layer and the doped amorphous silicon-containing layer 342 (such as doped and undoped amorphous silicon) and with no or minimal etching of the undoped crystalline silicon-containing capping layer and the first junction layer. As a result the undoped amorphous silicon containing layer and the doped amorphous silicon-containing layer are removed to while the first junction layer remains protected by at least a portion of the undoped crystalline silicon-containing capping layer. Thus, even if the selectivity is reduced at low temperatures, the first junction layer may be protected during selective etching. The etching process can include dry etching, wet etching, reactive ion etching, or other suitable etching methods. In embodiments, the etching process of operation is a self-aligned process, meaning that no etch mask is needed. Rather, the etching process of operation relies on the etch selectivity of the materials in the doped amorphous silicon-containing layer and the undoped amorphous silicon-containing layer relative to the undoped crystalline silicon-containing capping layer.

During the etching process, an etching gas is introduced in the processing region to selectively remove the amorphous silicon-containing layers relative to the crystalline silicon-containing layers. In embodiments, the etching gas is selected from chlorine, germane, germanium chlorides, or a combination thereof. In embodiments, the etching gas is selected from Cl₂, GeCl₂, GeCl₄, GeH₄, or a combination thereof. In embodiments, the etching gas is free from hydrogen chloride (HCl). In the present disclosure, the etching gas being free from hydrogen chloride (HCl) includes embodiments where the etching gas unintentionally contains HCl or otherwise contains a very low concentration of HCl such that the HCl gas does not etch under typical etching conditions. The etching gas may be introduced in the processing region at a flow rate in a range from about 1 sccm to about 1,000 sccm, or in a range from about 1 sccm to about 200 sccm, or in a range from about 1 sccm to about 100 sccm.

In embodiments, the doped amorphous silicon-containing layer and the undoped amorphous silicon-containing layer have an etch selectivity relative to the undoped crystalline silicon-containing capping layer 350 (i.e., an etch rate of the amorphous silicon-containing materials is higher than an etch rate of the silicon containing crystalline material). In some embodiments, the etch selectivity (i.e., a ratio of the etch rate of the amorphous silicon-containing materials to the etch rate of the silicon-containing crystalline material) is in a range from about 100:1 to about 3000:1, 300:1 to about 3000:1, or in a range from about 300:1 to about 2000:1, or in a range from about 300:1 to about 1500:1.

Nonetheless, the capping layer may then be removed to expose the first junction layer. The etch process may be selective to the undoped crystalline silicon-containing capping layer with no or minimal etching of the substrate and/or first junction layer. The etching process can include dry etching, wet etching, reactive ion etching, as well as other suitable etching methods. However, it should be clear that other selective low temperature epitaxial methods are contemplated herein.

After removal of the capping layer, or otherwise exposing a top surface of the first junction layer 420 (e.g. if no etching is needed), a second junction layer 418 is formed over first junction layer 420 at operation 325. However, as discussed above, in embodiments, operation 325 is performed in a second epitaxial growth chamber, such as a further processing chamber discussed above. In such a manner, the second junction layer may be formed with a different doping concentration than the first junction layer, without increasing the target doping concentration of the first junction layer (e.g. by automatically increasing the doping concentration due to residual dopant discussed above). In embodiments, a further clean operation may be utilized to ensure that no oxide is formed between the first junction layer and second junction layer. However, in embodiments, no further cleaning operation is necessary.

In embodiments, operation 325 may therefore deposit a second junction layer 418 having a high dopant concentration, over first junction layer 420. In embodiments, the second junction layer 418 may have a dopant concentration in the deposited layer of greater than or about 1×10¹⁹ cm⁻³, such as greater than or about 2×10¹⁹ cm⁻³, such as greater than or about 3×10¹⁹ cm⁻³, such as greater than or about 4×10¹⁹ cm⁻³, such as greater than or about 5×10¹⁹ cm such as greater than or about 6×10¹⁹ cm⁻³, such as greater than or about 7×10¹⁹ cm⁻³, such as greater than or about 8×10¹⁹ cm⁻³, such as greater than or about 9×10¹⁹ cm⁻³, such as greater than or about 1×10²⁰ cm⁻³, such as greater than or about 2×10²⁰ cm⁻³, such as greater than or about 3×10²⁰ cm⁻³, such as greater than or about 4×10²⁰ cm⁻³, such as greater than or about 5×10²⁰ cm⁻³, such as greater than or about 8×10²⁰ cm⁻³, such up to about 1×10²¹ cm⁻³, or such as less than 9×10²⁰ cm⁻³, such as less than or about 8×10²⁰ cm⁻³, or any ranges or values therebetween.

Depending upon the selective epitaxial growth process utilized, in embodiments, it may be desired or necessary to utilize the etch process discussed above in regards to the first junction layer. Namely, a capping layer and undoped layers may be formed over the second junction layer, and etched back according to any one or more of the processes discussed above.

In embodiments, after formation of second junction layer 418, it may be desired to create or improve a doping gradient extending from an exposed surface of the second junction layer, to an interface between the channels/substrate 402 and the first junction layer 420. While it should be understood that, in embodiments, more than two junction layers may be applied with various doping concentrations, in embodiments, it may be desirable to conduct an optional post anneal operation 330 to drive the dopant in, or further in, to the target feature. Annealing the semiconductor structure 400 can be accomplished by any suitable technique known in the art. However, in the present technology, the annealing may instead be conducted a temperature below the thermal budget. For example, in an inert atmosphere, the annealing may occur in a temperature range of about 300° C. to about 1100° C., or such as greater than or about 350° C. greater than or about 400° C., greater than or about 450° C., greater than or about 500° C., greater than or about 550° C., greater than or about 600° C., greater than or about 650° C., greater than or about 700° C., greater than or about 750° C., greater than or about 800° C., greater than or about 850° C., greater than or about 900° C., greater than or about 950° C., greater than or about 1000° C., or such as less than or about 1050° C., less than or about 1000° C., less than or about 950° C., less than or about 900° C., less than or about 850° C., less than or about 800° C., less than or about 750° C., less than or about 700° C., less than or about 650° C., less than or about 600° C., less than or about 550° C., less than or about 500° C., less than or about 450° C., or any ranges or values therebetween.

Namely, such a post-anneal operation may “smooth” the dopant gradient extending from the exposed surface of the second junction layer to or towards channels/substrate 402. In embodiments, a dopant concentration profile may therefore decline moving from the exposed/capacitor side surface of the second junction layer toward channels/substrate 402 in a linear or logarithmic manner. Regardless of the profile selected, the demarcations between the first junction layer and second junction layer, and/or first junction layer and the substrate may be blurred or blended, such that individual layers no longer remain in the respective junction after annealing. Of course, as discussed above, in embodiments, additional junction layers may be utilized in order to form the desired profile, or the thickness of the layers may be carefully controlled. For instance, as an example only, if a logarithmic provide is desired with a larger proportion of high dopant concentration to low dopant concentration, a thickness of the second junction layer may be deposited to be greater than a layer thickness of the first junction material, and vice-a-versa. However, if a linear profile is desired, the layers may be deposited so as to have a deposited thickness or depth that is relatively even.

Regardless of whether a post-anneal operation 425 is utilized, the semiconductor structure according to the now doped target region of the present technology may maintain the low oxide levels post doping. Thus, in embodiments, the doped target region (e.g., storage node junction/target region 412 in FIG. 4B), may contain less than or about 5 wt. % of oxides, including native oxides, such as less than or about 4 wt. %, such as less than or about 3 wt. %, such as less than or about 2 wt. %, such as less than or about 1 wt. %, such as less than or about 0.5 wt. %, such a less than or about 0.1 wt. %, or be generally free of oxides, based upon the total weight of the targeted region, at one or more of the doping depths or concentrations discussed above.

Nonetheless, as discussed above, the method 300 according to the present technology is well suited for doping a target region disposed within a recess, such as recess 404. Namely, the present technology may provide for the doping of features that lack a linear path from the target region to a process gas source. In embodiments, the recess may be generally perpendicular to a second feature that does contain a linear path to a process gas source. Additionally or alternatively, the methods discussed herein may also be well suited for doping regions disposed within channels or features having any of the lengths, widths, and/or aspect ratios discussed in regards to channels 402 above, such a features and channels.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing method comprising:
providing a semiconductor structure with one or more undoped non-line-of-sight target regions on a substrate within a semiconductor processing chamber, wherein one or more low thermal budget features are formed on the semiconductor structure;
subjecting the one or more undoped target regions to a pre-clean operation, removing at least a portion of any oxide present on the one or more undoped target regions;
epitaxially depositing a first junction layer having a first dopant concentration of less than 1×10²⁰ dopant atoms per cm³ over the substrate;
epitaxially depositing a second junction layer having a second dopant concentration of greater than 1×10¹⁹ dopant atoms per cm³ over the first junction layer;
wherein a temperature within the semiconductor processing chamber is maintained at less than or about 800° C.

2. The method of claim 1, wherein the temperature within the semiconductor processing chamber is maintained at less than or about 750° C.

3. The method of claim 1, further comprising subjecting the one or more target regions to a hydrogen bake prior to epitaxially depositing the first junction layer, wherein the hydrogen bake is conducted at a temperature of less than or about 750° C.

4. The method of claim 1, wherein the one or more target regions is disposed in a recess located within the semiconductor structure.

5. The method of claim 1, wherein the one or more target regions is disposed within a feature having a width of 10 nm or less.

6. The method of claim 1, wherein the semiconductor structure is maintained in an oxygen free atmosphere during the pre-clean operation, during epitaxially depositing the first junction layer, during epitaxially depositing the second junction layer, or a combination thereof.

7. The method of claim 6, wherein the pre-clean operation is integrated into the semiconductor processing chamber.

8. The method of claim 1, further comprising annealing the semiconductor structure after epitaxially depositing the second junction layer, wherein the annealing is conducted at a temperature of less than or about 1100° C.

9. The method of claim 8, wherein the annealing is conducted for a period of time and/or a temperature, forming a linear dopant gradient or a logarithmic dopant gradient, extending from an exterior surface of the second junction layer to the substrate.

10. The method of claim 1, wherein the one or more low thermal budget features include a bitline contact.

11. A semiconductor processing system, comprising:
a first processing chamber;
a second processing chamber;
a third processing chamber; and
a system controller configured to
remove at least a portion of any oxide present on one or more undoped target regions of a semiconductor structure in a first processing chamber, the one or more undoped target regions comprising one or more non-line-of-sight target regions on a substrate of a semiconductor structure positioned within a semiconductor processing chamber, wherein one or more low thermal budget features are formed on the semiconductor structure,
epitaxially deposit a first junction layer having a first doping concentration of less than 1×10²⁰ dopant atoms per cm³ over the substrate in a second processing chamber, and
epitaxially deposit a second junction layer having a second doping concentration of greater than 1×10¹⁹ dopant atoms per cm³ over the first junction layer in a third processing chamber.

12. The semiconductor processing system of claim 11, wherein the semiconductor processing system comprises a cluster tool.

13. The semiconductor processing system of claim 11, wherein the semiconductor processing system maintains an oxygen free atmosphere during the oxide removal, during epitaxially depositing the first junction layer, during epitaxially depositing the second junction layer, between oxide removal and epitaxially depositing the first junction layer, between epitaxially depositing the first junction layer and epitaxially depositing the second junction layer, or a combination thereof.

14. The semiconductor processing system of claim 11, wherein the semiconductor processing system maintains a temperature at less than or about 750° C.

15. The semiconductor processing system of claim 11, wherein the controller is further configured to subject the one or more target regions to a hydrogen bake prior to epitaxially depositing the first junction layer, wherein the hydrogen bake is conducted at a temperature of less than or about 750° C.

16. The semiconductor processing system of claim 11, wherein the controller is further configured to anneal the semiconductor structure after epitaxially depositing the second junction layer, wherein the annealing is conducted at a temperature of less than or about 1100° C.

17. A semiconductor processing system, comprising:
a system controller configured to
remove at least a portion of any oxide present on one or more undoped target regions of a semiconductor structure, the one or more undoped target regions comprising one or more non-line-of-sight target regions on a substrate of a semiconductor structure positioned within a semiconductor processing chamber, wherein one or more low thermal budget features are formed on the semiconductor structure,
epitaxially deposit a first junction layer having a first doping concentration of less than 1×10²⁰ dopant atoms per cm³ over the substrate,
epitaxially deposit a second junction layer having a second doping concentration of greater than 1×10¹⁹ dopant atoms per cm³ over the first junction layer;
wherein a temperature within the semiconductor processing chamber is maintained at less than or about 800° C.

18. The semiconductor processing system of claim 17, wherein the semiconductor structure comprises a 3D DRAM device.

19. The semiconductor processing system of claim 17, wherein the semiconductor structure comprises a 4F² device, wherein the one or more undoped target regions is disposed in or adjacent to a feature having a width of less than or about 10 nm.

20. The semiconductor processing system of claim 17, wherein the one or more undoped target regions has a length from an exposed surface to an interior end of greater than or about 40 nm.
